(19) United States
(12) Patent Application Publication
(10) Pub. No.: US 2007/0049071 A1
(43) Pub. Date: Mar. 1, 2007

(54) Recharging apparatus for portable electronic devices

(76) Inventors: W. Shaun Jackson, Ann Arbor, MI (US); Mark Zadvinskis, Ann Arbor, MI (US)

Correspondence Address: John G. Posa;Gifford, Krass, Groh, Sprinkle,, Anderson & Citkowski, PC, PO Box 7021, Troy, MI, 48007-7021, US

(21) Appl. No.: 11/481,353

(22) Filed: Jul. 5, 2006

Related U.S. Application Data
(60) Provisional application No. 60/696,638, filed on Jul. 5, 2005.

(51) Int. Cl. H05K 1/00

(52) U.S. Cl. 439/79

(57) ABSTRACT

A portable electronic device includes a plurality of externally accessible electrical contacts, enabling electrical current or data to flow to or from the device when the device is “closed” or not being used. The invention is applicable to all types of portable devices, including laptop, notebook and palm-top computers, as well as telecommunications devices, video players and music players. Typically the externally accessible electrical contacts allow a battery in the device to be recharged. The preferred embodiment facilitates the recharging of a plurality of devices contained in lockers, carts, or other types of “docking stations.” The docking bay includes a corresponding set of electrical contacts configured to electrically engage with the contacts on the device. Such a docking bay may take the form of a charging stand, a cart with one or more slots or compartments, or a locker with a door and a storage compartment. A light may be provided on the device or the docking bay indicating that the electrical current is flowing from the bay to the device.

### REFERENCE TO RELATED APPLICATION

This application claims priority to U.S. Provisional Patent Application Serial No. 60/696,638, filed Jul. 5, 2005, the entire content of which is incorporated herein by reference.

### FIELD OF THE INVENTION

This invention relates generally to the recharging of portable electronic devices and, in particular to systems and methods for recharging such devices while contained in lockers, carts, and the like.

### BACKGROUND OF THE INVENTION

It is becoming increasingly popular to provide schoolchildren with laptop computers which they obtain from a cart or locker in the classroom. U.S. Pat. Nos. 6,008,621 and 6,218,796 show such storage carts. Some of these notebook computer carts are also commercially available from various sources.

One of the problems with these arrangements is that students, particularly younger children, can drop the computer while removing or returning the device from and to its storage compartment, thereby costing the school considerable funds. Problems may also arise in the wiring associated with plugging and unplugging the recharger, resulting in dead batteries or poor contacts. The need remains, therefore, for a system which is relatively fool-proof in terms of charging.

### SUMMARY OF THE INVENTION

This invention improves upon existing systems by providing a portable electronic device having a plurality of externally accessible electrical contacts, enabling electrical current or data to flow to or from the device when the device is “closed” or not being used. The invention is applicable to all types of portable devices, including laptop, notebook and palm-top computers, as well as telecommunications devices, video players and music players.

Typically the externally accessible electrical contacts allow a battery in the device to be recharged. To reduce shorting, one or more of the electrical contacts may protrude from the device, or one or more of the electrical contacts may be recessed. One or more of the electrical contacts may be adapted to magnetically engage with a corresponding set of electrical contacts, and a light may be provided on the device or the docking station to indicate that the device is being properly charged.

The preferred embodiment facilitates the recharging of a plurality of devices contained in lockers, carts, or other types of “docking stations.” The docking bay includes a corresponding set of electrical contacts configured to electrically engage with the contacts on the device. Such a docking bay may take the form of a charging stand, a cart with one or more slots or compartments, or a locker with a door and a storage compartment. A light may be provided on the device or the docking bay indicating that the electrical current is flowing from the bay to the device.

### BRIEF DESCRIPTION OF THE DRAWINGS

FIG. 1 is an oblique drawing showing a preferred embodiment of the invention; and

FIG. 2 is a detail drawing in partial cross section which shows the way in which a spring-loaded contact from a power supply makes contact to a pad on a computer which, in turn, makes electrical connection to the computer's battery and/or charging system.

### DETAILED DESCRIPTION OF THE INVENTION

Broadly, this invention resides in cases and corresponding storage facilities that enable a portable electronic device to be recharged during periods when it is not in use. The invention is applicable to all types of portable electronic devices, including laptop, notebook and palm-top computers, as well as telecommunications devices, video players and music players.

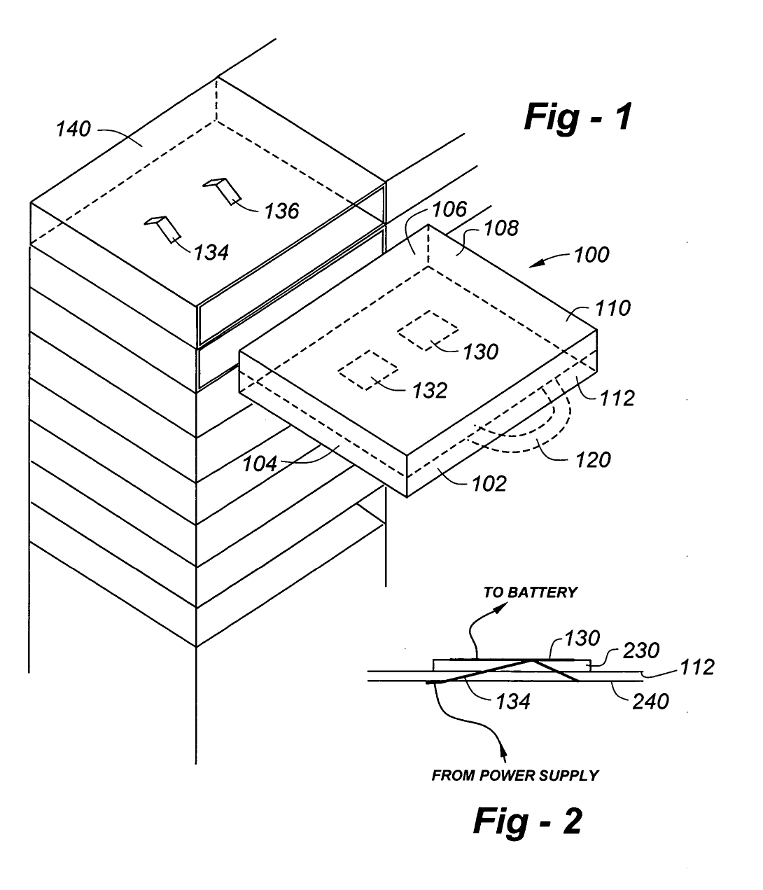

FIG. 1 is an oblique drawing showing a preferred embodiment of the invention, and FIG. 2 is a drawing that shows the details of a contact mechanism. Referring to FIG. 1, a computer 100, which may be a laptop, notebook, palm-sized computer, or the like, includes side edges 102, 104, 106, 108 and top/bottom surfaces 110, 112. An optional handle 120 may be provided on any of the edges. The size or dimensions of the unit are not germane to the invention, other than it should be received in slip-fit fashion into receptacle 140 having electrical contacts 134, 136.

The contacts 134, 136 are aligned with contacts 132, 130 on the computer 100, such that when the device is placed into the slot 140, contact is made, allowing the computer to be charged from an appropriate source of power (not shown).

Although two contacts are shown, more may be used, depending upon the brand of the computer maker. Indeed, if the case is used as a ground contact, only a single distinct power contact need be provided in some instances. The contacts 130, 132 may either be factory-installed on the computer 100, or a separate bracket may be used (not shown), providing two or more electrical paths, as well as an electrical interconnect to make connection to the computer's port for battery charging. This would allow the system described herein to be used with existing portable electronic devices. Although the contacts 130, 132 are shown on the “bottom” of the unit, they may be provided on any of the sides 102, 104, 106, 108, including on opposing sides, to better prevent shorting out. One or more contacts may be placed on the top as well, 106.

FIG. 2 is a detail drawing in partial cross section which shows the way in which a spring-loaded contact 134 from a power supply makes contact to a pad 130 on the computer which, in turn, makes electrical connection to the computer's battery and/or charging system. The surface 112 of the computer may include a recess 230 into which pad 130 is situated, again, to help prevent undesired electrical contact with metal objects. 240 is the inner surface of one of the receptacles 140.

According to the invention, slot 140 is replicated to provide a storage cart, locker facility, or other bank of slots, each having electrical contacts which mate with a corresponding computer. In this way, particularly in educational environments, younger adults and children may place and remove their computers into the cart/locker, without having to connect a cable from the cart or locker to the computer, which not only creates the reliability problems, but might also result in the computer being dropped and damaged.

Although not shown, the case of the computer 100 may include some sort of resilient or shock-absorbing material to help prevent damage during placement and removal of the device in the cabinet. Also, although horizontal slots are shown, vertical or diagonal arrangements may also be used.

I claim:

1. A recharging system for, comprising:
a portable electronic device including a rechargeable battery;
a plurality of externally accessible electrical contacts on the device enabling electrical current to flow to the rechargeable battery; and
a docking bay configured to receive the portable electronic device, the bay including one or more electrical contacts in physical correspondence with the contacts on the device; and
the contacts in the bay being in electrical communication with a source of power, such that the battery in the portable electronic device is automatically recharged when the device is placed in the bay.

2. The system of claim 1, wherein the device is a computer.

3. The system of claim 1, wherein one or more of the electrical contacts protrude from the device.

4. The system of claim 1, wherein one or more of the electrical contacts on the device are recessed.

5. The system of claim 1, wherein one or more of the electrical contacts between the device and the docking bay magnetically engage when the device is placed in the bay.

6. The system of claim 1, further including light indicating that the electrical current is flowing from the docking bay to the device.

7. The system of claim 1, wherein the docking bay is a charging stand with a set of electrical contacts configured to electrically engage with the contacts on the device.

8. The system of claim 1, wherein the docking bay is a cart with a plurality of storage compartments, each compartment having a set of electrical contacts configured to electrically engage with the contacts on one of the devices.

9. The system of claim 1, wherein the docking bay is a locker with a storage compartment having a set of electrical contacts configured to electrically engage with the contacts on one of the devices.
